(19) United States
(12) Patent Application Publication
(10) Pub. No.: US 2013/0167907 A1
(43) Pub. Date: Jul. 4, 2013

(54) Photovoltaic Mounting Apparatus and Method of Installation

(71) Applicants: Panagiotis G. Bitarchas, Athens (GR); Spyridon N. Kottaras, Athens (GR); Emmanouil E. Vergetis, Athens (GR)

(72) Inventors: Panagiotis G. Bitarchas, Athens (GR); Spyridon N. Kottaras, Athens (GR); Emmanouil E. Vergetis, Athens (GR)

(21) Appl. No.: 13/343,183

(22) Filed: Jan. 4, 2012

(51) Int. Cl. H01L 31/048; H01L 23/32; E02D 7/00; H01L 31/18

(52) U.S. Cl. 136/251; 29/890.033; 211/41.1; 405/232

(57) ABSTRACT

A photovoltaic mounting apparatus includes a mounting frame coupled to a pile capable of being anchored in numerous terrain and slope conditions, universal clamping for mounting any type of solar panel thereto, and components enabling customized angles of inclination of photovoltaic modules mounted onto the frame. Optimized testing and preparation for installation are part of a process ensuring that design of materials and installation of a photovoltaic mounting apparatus is customizable to reduce time and expense in a method of installation.

### CROSS REFERENCE TO RELATED PATENT APPLICATIONS

Not applicable.

### STATEMENT REGARDING FEDERALLY-SPONSORED RESEARCH OR DEVELOPMENT

Not applicable.

### FIELD OF THE INVENTION

The present invention relates generally to photovoltaics. More specifically, particular embodiments of the invention relate to fixed-axis photovoltaic mounting apparatus and components, and optimized methods of installing same.

### BACKGROUND OF THE INVENTION

There are many conventional fixed-axis mounting systems for photovoltaics that have existed and been in use for many years. The basic premise of all such systems is the same—to capture solar energy and convert it for use as a source of electrical power. Existing mounting systems have been historically limited by high installation and product costs. Factor in such high costs include limitations on places where such mounting systems can be installed, and the lack of available customization. As technology develops, governmental subsidies for clean energy increase, and market conditions for implementing photovoltaic solutions improves, needs have arisen for photovoltaic mounting systems that are customizable and at the same easily installable in a variety of terrain and environmental conditions in both industrial and residential applications.

For example, in existing single and double-pile mounting systems, customization is limited by structures that fix angles of inclination of mounting systems and make it difficult for designs, engineers, and installers to alter the tilt of a mounting system based on customer need or environmental requirements. Typically, mounting frames are directly bolted to piles at inclination angles that, once fixed, cannot be changed with significant effort by an installation team, resulting in higher operating costs for providers.

Additionally, there are many conventional ways to secure photovoltaic modules to fixed-axis mounting frames. Conventional clamps are one such method. These are usually bolted to the frame itself, requiring the components to which clamps are bolted to have been machined to accept such clamps, resulting in a component cost increase. Clamps which bolt directly to a frame are difficult to adjust and cannot be easily moved, significantly reducing the degree of customization available for the installer, and increasing the effort needed to fasten a photovoltaic module to a fixed-axis mounting frame. Other clamps are snap-on clamps that drastically reduce mounting time, but do not provide a stable method of securing expensive photovoltaic modules, leaving them susceptible to damage.

Installation of existing photovoltaic mounting systems can also cumbersome and expensive, as specialized equipment and a well-trained team of people must be present. Components are usually not optimized to minimize the time and expense needed for a team of people to quickly install a mounting system, and often challenges in the environment in which the mounting system is to be installed adds extra levels of complexity to the installation. Existing mounting systems thereby limit customization and problem-solving at the point of installation, which in term limit the effectiveness of photovoltaic mounting systems.

It is therefore one object of the present invention to teach a photovoltaic mounting apparatus with a design that is customizable and which optimizes the use of materials, is compatible with and scalable to the challenging requirements of today's technology, and is easily and quickly installable in a variety of environmental conditions and for a variety of customer requirements.

### BRIEF SUMMARY OF THE INVENTION

The present invention discloses a photovoltaic mounting system and methods of installing the same. The photovoltaic mounting system of the present invention is known by its trade name KIVO and comes in many different embodiments, depending at least in part upon the type of ground or surface to which the photovoltaic mounting in system will be installed. The KIVO mounting system therefore can be thought of as a series of products with different designations, such as for example CR or TF for crystalline or thin-film photovoltaic modules in open-area mounting systems, respectively, and IR and TR for industrial roofing and tiled roofing, respectively, in roof-mounted installations.

Every photovoltaic installation is unique and customized to each client's particular requirements. KIVO mounting systems according to the present invention are based on high-quality materials, such as galvanized, cold-rolled steel, and are designed to minimize weight. They are also resistant to all weather conditions and are designed to be deployed quickly and easily by a minimum number of installation team members.

In one embodiment, a photovoltaic mounting apparatus comprises a plurality of purlins, each purlin coupled to a plurality of transverse beams with one or more connective elements to form a fixed-axis mounting frame, and at least one inclination assembly connecting each transverse beam in the plurality of transverse beams of the fixed-axis mounting frame to a pile, each at least one inclination assembly including a bracing element connecting the pile to each transverse beam at a first connection point on the transverse beam, and an inclination element connecting the bracing element to the transverse beam at a second point on the transverse beam, each inclination element having a plurality of apertures for connecting to the second connection point on the transverse beam to form an adjustable angle of inclination of the fixed-axis mounting frame relative to the pile, each pile configured to anchor the fixed-axis mounting frame to terrain as determined by one or more environmental conditions, and a plurality of intermediate clamps each removably and adjustably disposed at any point along a purlin to secure photovoltaic modules together, and a plurality of end clamps each removably and adjustably disposed near ends of a purlin to secure a photovoltaic module in place on the fixed-axis mounting relative to an intermediate clamp, each of the intermediate clamps and each of the end clamps having an aperture through which a screwing mechanism firmly connects each clamp to a hook slidably disposable along an edge of a purlin with tension applied between the hook and the clamp, so that each hook, clamp, and screwing mechanism form a clamping assembly that is removably positionable at a desired point on a purlin and firmly couples to the purlin to allow photovoltaic modules to be slidably and securely mounted onto the fixed-axis mounting frame and to allow one or more electrical cables to be positioned along an inner surface of each purlin to be free of interference from weather elements.

In another embodiment of the present invention, a method of installing a photovoltaic mounting system comprises anchoring a pile with an appropriate foundation optimally determined by analyzing environmental conditions and the geotechnical characteristics of soil determined by a plurality of tests that include a ramming test, a geotechnical analysis, a soil pH test, and a study of land topography, so that the appropriate foundation provides an optimum support for a fixed-axis mounting frame coupled to the pile, and fastening the fixed-axis mounting frame to each pile at a desired angle of inclination determined by at least one of customer requirements and environmental conditions, the angle of inclination arranged with an inclination assembly that couples transverse beams of the fixed-axis mounting frame to the pile, the inclination assembly including a bracing element coupling to a first connection point on each transverse beam and an inclination element coupling to a second connection point on each transverse beam, the inclination element having a plurality of apertures through which the inclination element is adjustably coupleable to each transverse beam to form the desired angle of inclination relative to the pile. The method also comprises positioning a plurality of pre-fabricated clamping assemblies onto purlins coupled to the fixed-axis mounting frame and removably securing each pre-fabricated clamping assembly to the purlins with a screwing mechanism so that tension applied between a hook and a clamp of each pre-fabricated clamping assembly slidably positions each pre-fabricated clamping assembly at a desired point on a purlin and firmly couples to a purlin, leaving an inner surface of each purlin, and mounting one or more photovoltaic modules onto the purlins by slidably positioning each photovoltaic module onto the fixed-axis mounting frame between at least two of the pre-fabricated clamping assemblies, the plurality of pre-fabricated clamping assemblies including intermediate clamps configured to secure two photovoltaic panels together and end clamps configured to position panels between an end clamp and an intermediate clamp and near an edge of a purlin.

In another embodiment of the present invention, a customizable photovoltaic mounting system comprises an inclination assembly coupling a transverse beam of a fixed-axis mounting frame to a support end of a pile at an angle adjustable according to at least one of customer and environmental requirements, and a plurality of pre-fabricated clamping assemblies each having a hook portion slidably disposable along a ridged portion of a purlin and a clamp portion secured to the hook portion with a screwing mechanism so that one or more photovoltaic modules are securely positionable in a plurality of configurations according to the at least one of customer and environmental requirements on the fixed-axis mounting frame by a force exerted on the purlin between the hook and the clamping portion that permits each pre-fabricated clamping assembly to be adjusted and positioned, and a number of the pre-fabricated clamping assemblies used to be determined, according to the at least one of customer and environmental requirements, the purlin having an inner surface capable of housing a cable providing electrical connectivity to the one or more photovoltaic modules in a position protecting the cable from interference.

Other embodiments, features, objects, and advantages of the KIVO mounting system of the present invention and methods of installing the KIVO mounting system will become apparent from the following description of the embodiments, taken together with the accompanying drawings, which illustrate, by way of example, the principles of the invention.

### BRIEF DESCRIPTION OF THE SEVERAL VIEWS OF THE DRAWINGS

The accompanying drawings, which are incorporated in and constitute a part of this specification, illustrate several embodiments of the invention and together with the description, serve to explain the principles of the invention.

FIG. 1 is a side schematic view of a photovoltaic mounting apparatus according to the present invention;

FIG. 2 is a perspective view of a photovoltaic mounting apparatus according to the present invention;

FIG. 3 is a close-up perspective front view of an inclination assembly and a fixed-axis mounting frame according to the present invention;

FIG. 4 is a close-up perspective rear view of an inclination assembly and a fixed-axis mounting frame according to the present invention;

FIG. 5 is a close-up perspective view of a photovoltaic mounting apparatus and photovoltaic modules being mounted onto a fixed axis mounting frame thereof according to the present invention;

FIG. 6 is a close-up isometric view of an intermediate clamp and assembly according to the present invention;

FIG. 7A is a close-up side view of an intermediate clamp according to the present invention;

FIG. 7B is another close-up side view of an intermediate clamp according to the present invention;

FIG. 8 is a close-up isometric view of an end clamp and assembly according to the present invention;

FIG. 9A is a close-up side view of an end clamp according to the present invention;

FIG. 9B is another close-up side view of an end clamp according to the present invention

FIG. 10 is a close-up isometric view of purlins coupled together and to a transverse beam and an inclination assembly with apertures, and connected with the transverse beam at an inclined angle according to the present invention;

FIG. 11 is a close-up isometric view of an inclination assembly with apertures and connected with a transverse beam at an inclined angle according to the present invention;

FIG. 12A is a multi-dimensional exploded view of a photovoltaic mounting apparatus for installation on industrial roofing according to one embodiment of the present invention;

FIG. 12B is a close-up sectional view of a photovoltaic mounting apparatus for installation on industrial roofing according to the embodiment of the present invention shown in FIG. 12A;

FIG. 13 is another multi-dimensional view of a photovoltaic mounting apparatus for installation on industrial roofing according to the embodiment of the present invention of FIG. 12A;

FIG. 14A is a partially exploded view of a photovoltaic mounting apparatus for installation on tile roofing according to one embodiment of the present invention;

FIG. 14B is a close-up view of a portion of a photovoltaic mounting apparatus on tile roofing according to the embodiment of FIG. 14A;

FIG. 14C is another close-up view of a portion of a photovoltaic mounting apparatus on tile roofing according to the embodiment of FIG. 14A; and

FIG. 14D is a side view of an end of a portion of a photovoltaic mounting apparatus on tile roofing according to the embodiment of FIG. 14A.

### DETAILED DESCRIPTION OF THE INVENTION

In the following description of the present invention reference is made to the accompanying figures which form a part thereof, and in which is shown, by way of illustration, exemplary embodiments illustrating the principles of the present invention and how it is practiced. Other embodiments will be utilized to practice the present invention and structural and functional changes will be made thereto without departing from the scope of the present invention.

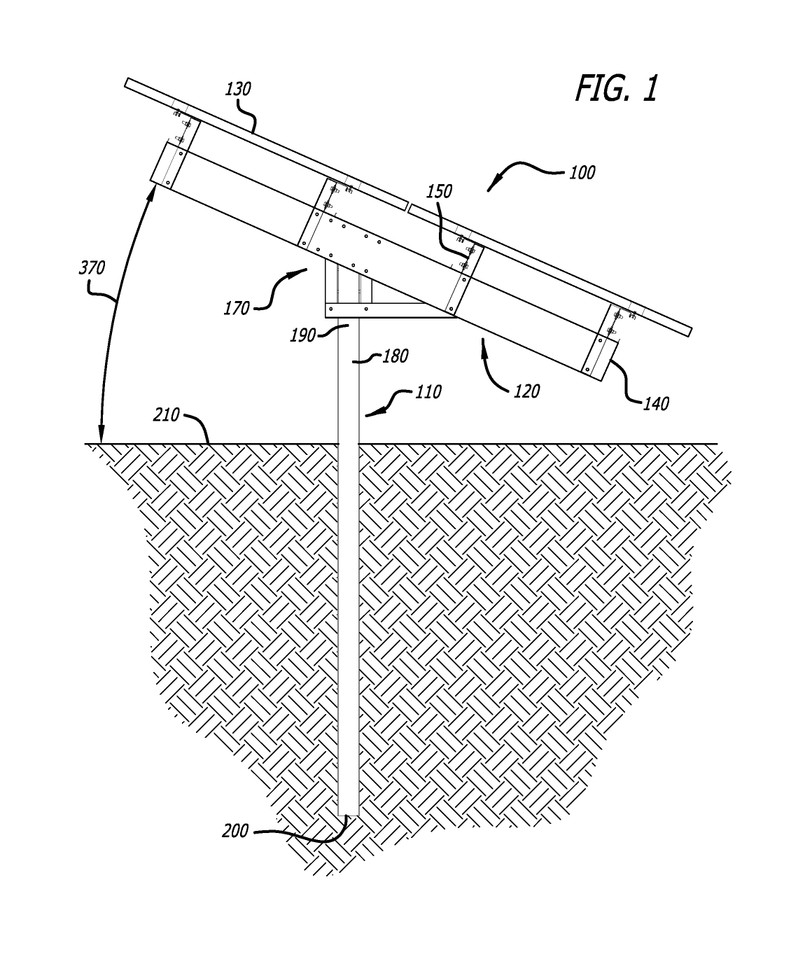

A KIVO photovoltaic mounting system is shown in FIG. 1, which is a side schematic view of a photovoltaic mounting apparatus 100 according to the present invention. The photovoltaic mounting apparatus 100 includes a pile 110 supporting a fixed-axis mounting frame 120 onto which one or more photovoltaic modules 130 are to be installed. The fixed-axis mounting frame 120 includes transverse beams 140 coupled to purlins 150 by connective elements 160. Each transverse beam 140 is coupled to a pile 110 by an inclination assembly 170 configured so that the fixed-axis mounting frame 120 is angularly adjustable according to at least one of use, customer or project requirements and environmental conditions or requirements.

The pile 110 includes a beam 180 having a support end 190, to which the inclination assembly 170 is coupled, and a foundation end 200 which is anchored to terrain 210. The photovoltaic mounting apparatus 100 may include a single pile foundation or a multi-pile foundation, such as a double pile. In a single pile foundation, a single beam 180 is used to anchor to terrain 210 and provide support to the fixed-axis mounting frame 120. In a multi-pile foundation, at least two beams 180, coupled to the transverse beam 140 at different positions, are used to anchor to terrain 210 and to provide support to the fixed-axis mounting frame 120.

The photovoltaic modules 130 are secured to the fixed-axis mounting frame 120 with a plurality of clamping assemblies 220. The clamping assemblies 220 are each comprised of clamping portions 230, hook portions 240, and screwing mechanisms 250. The clamping portions 230 include intermediate clamps 260 and end clamps 270, for securing photovoltaic modules 130 to the fixed-axis mounting frame 120.

The present invention contemplates that materials used to manufacture the photovoltaic mounting apparatus 100, including at least the piles 110, transverse beams 140, and purlins 150, are all composed of material that minimizes environmental impact during manufacturing and results in products that are lighter and therefore easier to transport and install, yet provide for a high level of field performance. Steel is one such material. A type of steel that may be used in the present invention is galvanized cold-formed steel, and in one embodiment of the present invention, a manufacturing process known as UltraSTEEL™ is used for various components of the photovoltaic mounting apparatus 100. Such a process increases the strength of base metals used, providing stronger, better performing, lighter, and more environmentally-friendly materials.

The inclination assembly 170 is comprised of a bracing element 280 and at least one inclination element 290. Each bracing element 280 is coupled on a first end 300 to a first connection point 310 on the transverse beam 140. A second end 320 of each bracing element is positioned substantially perpendicular to the beam 180 of the pile 110, and connects to a lower end 330 of each inclination element 290. Where a single inclination element 290 is employed, connection with the bracing element 280 may occur with the second end 320 of the bracing element 280 on either side of the beam 180. In embodiments where there are multiple inclination elements 290 such as that shown in FIG. 1 and FIG. 11, each lower end 330 of each inclination element 290 connects to the second end 320 of the bracing element 280 on either side of the beam 180 of the pile 110. Regardless, the inclination element 290 and the bracing element 280, when coupled together, form a 90° angle relative to each other, so that the beam 180 and the inclination element 290 are both substantially perpendicular to the bracing element 280.

An upper end 340 of each inclination element 290 is coupled at a second connection point 350 along the transverse beam 140. Apertures 360 in the inclination element 290 allow the point at which the inclination element 290 couples to the second connection point 350 on the transverse beam 140 to be easily adjustable by the installation team, so that an angle of inclination 370 of the fixed-axis mounting frame 120 relative to the pile 110 and the terrain 210 can be customized.

It is often the situation in photovoltaic installations that angles of inclination at which photovoltaic modules 130 are mounted are important, due to a variety of factors such as environmental conditions or requirements 380 and use, customer, or project requirements 390. Examples of environmental conditions or requirements 380 that may affect, and alter, the angle of inclination include, but are not limited to, the type of terrain 210 on which the photovoltaic mounting apparatus 100 is installed, the slope of such terrain 210, the type of soil, weather and sunlight conditions, etc. Examples of use, customer, or project requirements 390 that may affect, or alter, the angle of inclination include, but are not limited to, the size and number of photovoltaic mounting apparatuses 100 to be installed, the size and number of photovoltaic modules 130 to be installed, the amount of power desired to be generated, the purchase needs of buyers of solar power generated, etc. Angles of inclination of the fixed-axis mounting frame 120 relative to the terrain or roof surface may vary, usually in a range of between 10° and 40°. However, it is to be understood that any angle or range of angles of inclination may be utilized in order to maximize performance of the photovoltaic mounting apparatus 100.

The inclination assembly 170 of the present invention is designed to be easily adjustable by the installation team so that the angle of inclination 370, and the fixed-axis mounting frame 120, can be customized. It is contemplated that customization can occur easily at the time of installation and at any time during the usage history of the photovoltaic mounting apparatus 100, so that if use, customer, or project requirements 390, and/or environmental conditions or requirements 380, change during the course of usage of the present invention, adjustments and alterations of the photovoltaic mounting apparatus 100 are easily made.

In another embodiment of the present invention, the photovoltaic mounting apparatus 100 may be assembled with a transverse beam 140 directly coupled to a pile 110 either without the use of an inclination assembly that includes inclination elements 290 and a bracing element 280, or with an inclination assembly 170 that includes a single inclination element 290 coupled to a bracing element 280. Accordingly, the choice of using inclination assemblies 170 and associated elements is a choice dependent on a variety of parameters. One such parameter is an assessment of installation difficulties, and often it is desired to eliminate or reduce the possibility of mistakes or make it easier for an installation team to quickly and safely complete their task. In one example of this, difficult terrain 210 may make installation more complex, and therefore reducing the number of parts involved reduces the chance of installation errors. It is to be noted that angles of inclination 370 may still be achieved in such an example without the use of inclination assemblies 170, particularly where piles are rammed in different directions due to terrain complexities.

Another parameter involves positioning of the photovoltaic mounting apparatus 100 relative to the expected solar exposure at the installation site—often, angles of inclination 370 are either not as important, or can be achieved by other means that use less parts. For example, holes in both the pile 110 and the transverse beam 140 may be utilized to achieve a desired angle of inclination 370 where adjustments do not need to be made, especially where terrain 210 does not have an impact on the amount of solar exposure. One such situation is in flat field installations, where angles of inclination 370 are not needed.

It is therefore to be understood that an inclination assembly 170 according to the present invention may comprise alternate configurations than that described above. In one such alternate configuration, the inclination assembly includes one inclination element 290 coupled to one bracing element 280. In another such alternate configuration, the inclination assembly 170 is one or more bolts, screws, or other such mechanisms that couple the pile 110 to the transverse beam 140 directly, via holes in both the pile 110 and the transverse beam 140.

The photovoltaic mounting apparatus 100 of the present invention is suitable for installation of different types of photovoltaic modules 130. It is therefore understood that photovoltaic modules 130 to be installed with the present invention may include all industry-standard modules, including but not limited to framed modules based on wafer-based mono-crystalline and poly-crystalline silicon cells or thin-film cells based on material such as cadmium telluride or silicon, as well as frameless modules based on thin-film cells as discussed herein.

The photovoltaic mounting apparatus 100 of the present invention is comprised predominantly of galvanized cold-formed steel materials. Use of such materials offers significant advantages due to lower cost, longer life, and ease of transportation. Pre-fabricated clamping assemblies 220 are substantially comprised of aluminum. Many different types of commercially-available aluminum alloys are contemplated and may be utilized for clamping assemblies 220, such as for example EN AW-6063 T6 aluminum.

The photovoltaic mounting apparatus 100 of the present invention utilizes components that are comprised of materials standard to the steel industry all over the world, making their manufacture and use easy for design and installation. Therefore, piles 110 comprised of any kind of standard section can be used, such as for example IPE, C, Sigma, and RHS. Similarly, any standard transverse beam configurations may also be used in the present invention, such as for example those having “C” and “Σ” shapes. This allows the present invention to be manufactured around the world using standard manufacturing equipment, so that no additional or new equipment is needed, thereby keeping costs to a minimum.

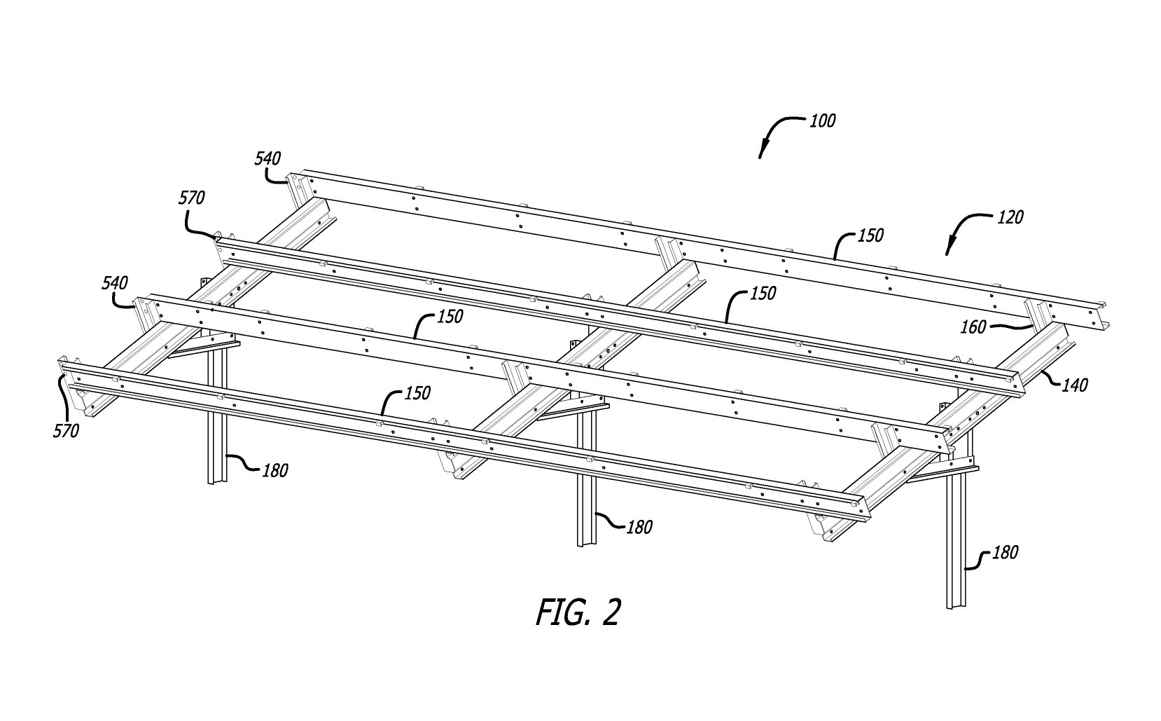

FIG. 2 is a perspective view of a photovoltaic mounting apparatus 100. FIG. 2 demonstrates a photovoltaic mounting apparatus 100 with a plurality of piles 110, a plurality of transverse beams 140, and a plurality of purlins 150 in a single-pile arrangement in which each pile 110 supports a transverse beam 140. In a double-pile arrangement, two piles 110 would support each transverse beam. The present invention contemplates that any number of transverse beams 140 may be included in a photovoltaic mounting apparatus 100 of the present invention to form a fixed-axis mounting frame 120, so that the present invention is scalable to allow customization for varying numbers of photovoltaic modules 130.

It is also to be noted that while FIG. 2 shows four purlins 150, any number of purlins 150 may be used, and of any length. Additionally, since single or multi-pile arrangements are contemplated, it is to be understood that transverse beams 140 therefore need not have a particular length. Accordingly, there are no predetermined numbers of piles 110, transverse beams 140, or purlins 150 that are contemplated by the present invention, making the photovoltaic mounting apparatus 100 completely customizable according to the environmental conditions or requirements 380 and the use, customer, or project requirements 390.

It is important to note that the use of purlin connectors 540 as described herein to connect purlins 150 together allow purlins 150 of any length to be utilized. Joints such as the purlin connectors 540 allow a space between adjoining purlins 150, thereby accounting for thermal stress under varying weather conditions at an installation site.

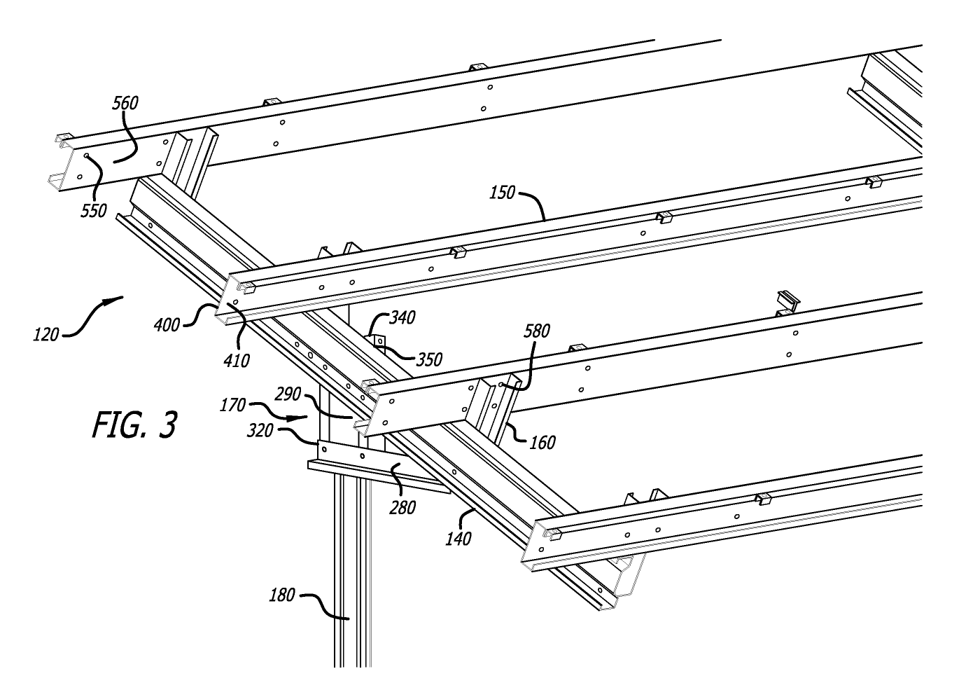

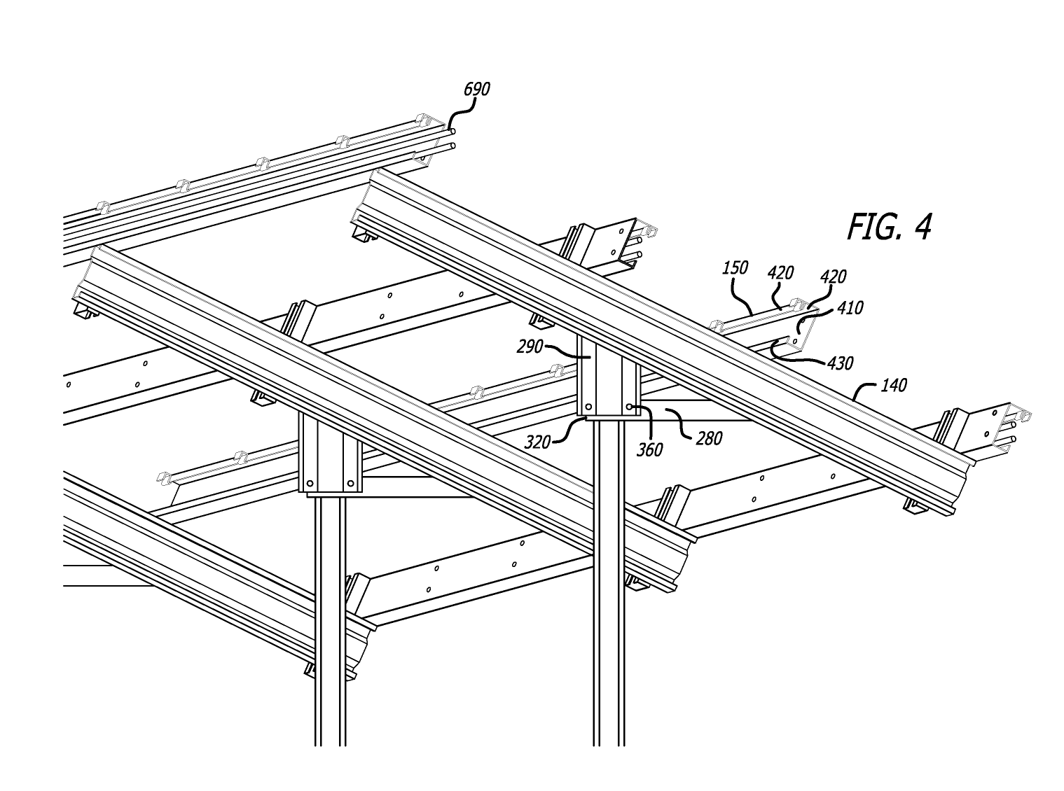

FIG. 3 and FIG. 4 are close-up perspective front and rear views, respectively, of an inclination assembly and a fixed-axis mounting frame according to the present invention. Both FIG. 3 and FIG. 4 show that purlins 150 are coupled to the transverse beams 140 by connective elements 160 to form the fixed-axis mounting frame 120, onto which photovoltaic modules 130 are to be mounted. Connective elements 160 are fastened to a transverse beam 140 and to a purlin 150 to form a stable, secure, and sturdy mounting environment for photovoltaic modules 130. Each connective element 160 is fastened to a transverse beam 140 in a substantially perpendicular manner so that a purlin 150 adopts the same angle of inclination as the transverse beam 140 by way of the inclination assembly 170. In the embodiment of FIG. 3 and FIG. 4, connective elements 160 are fastened to an outer surface 400 of a purlin 150 so that the purlin 150 is substantially perpendicular to the transverse beam 140 it is coupled to, as noted above.

Each purlin 150 also has an inner surface 410 and cornered ends 420 each forming a ridged portion 430, as shown in FIG. 3 and FIG. 4. Each purlin 150 therefore has the general shape of a “C” which allows for cables to be easily routed along the inner surface 410 and the cornered ends 420 as discussed herein. As described in detail herein, the present invention includes a plurality of pre-fabricated clamping assemblies 220 which are slidably positionable on each purlin 150 along one of the ridged portions 430 of the cornered ends 420 and secured thereon using a screwing mechanism 250 that is part of each pre-fabricated clamping assembly 220. The pre-fabricated clamping assemblies 220 secure the photovoltaic modules 130 in place on the fixed-axis mounting frame 120. Use of such pre-fabricated mounting assemblies 220 eases the installation process for a photovoltaic mounting apparatus 100 by reducing time and complexity, and therefore cost.

Use of such pre-fabricated clamping assemblies 220 also has the benefit of allowing electrical cables 690 to be positioned along the inner surface 410 of a purlin 150 free of obstruction from other components and protected from weather conditions for providing electrical connections to components of the photovoltaic mounting apparatus 100, provide power to the photovoltaic modules 130 and photovoltaic mounting apparatus 100, and provide connectivity between photovoltaic modules 130 and inverters to harvest electricity and/or solar energy generated therefrom. This allows for a reduction in time and expense of installing electrical components as no additional cable adjustment materials are needed to secure the electrical cables 690.

FIG. 5 is a close-up perspective view of photovoltaic modules 130 being mounted onto a fixed axis mounting frame 120 of a photovoltaic mounting apparatus 100 according to the present invention. FIG. 5 shows that photovoltaic modules 130 are laid on top of purlins 150 proximate to an outer surface 440 of a ridged portion 430. FIG. 5 also shows pre-fabricated clamping assemblies 220 and intermediate clamps 260 that secure two photovoltaic modules 130 together on the fixed-axis mounting frame 120.

Photovoltaic modules 130 are installed onto a fixed-axis mounting frame 120 in a process that allows for any type and size of photovoltaic module 130 in any configuration and in any number to be easily and quickly positioned and secured on the photovoltaic mounting apparatus 100. Hook portions 240 of the pre-fabricated clamping assemblies 220 are slidably positionable along a ridged portion 430 of a cornered end 430 of a purlin 150 to any point on the purlin 150. The hook portions 240 do not need to couple to any part of the purlin 150, so that no screws, bolts, or other fasteners are required.

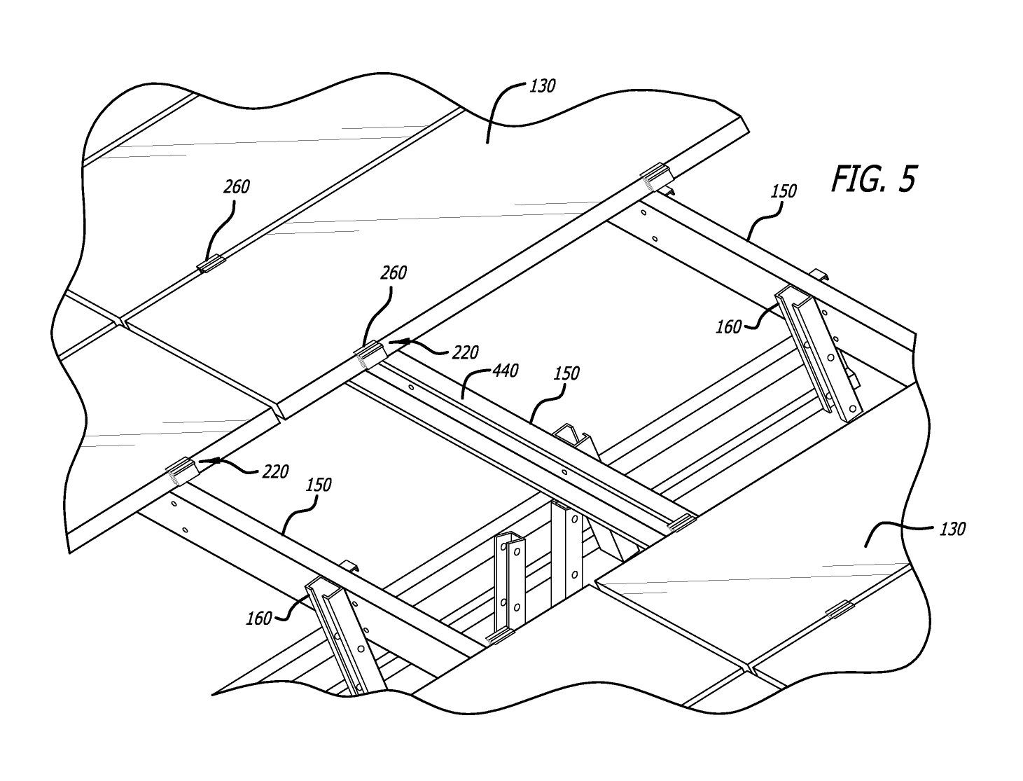

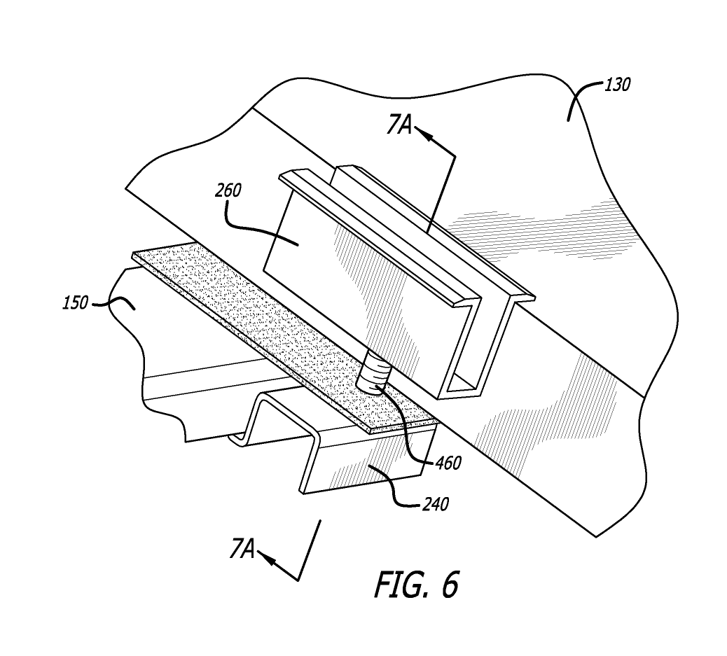

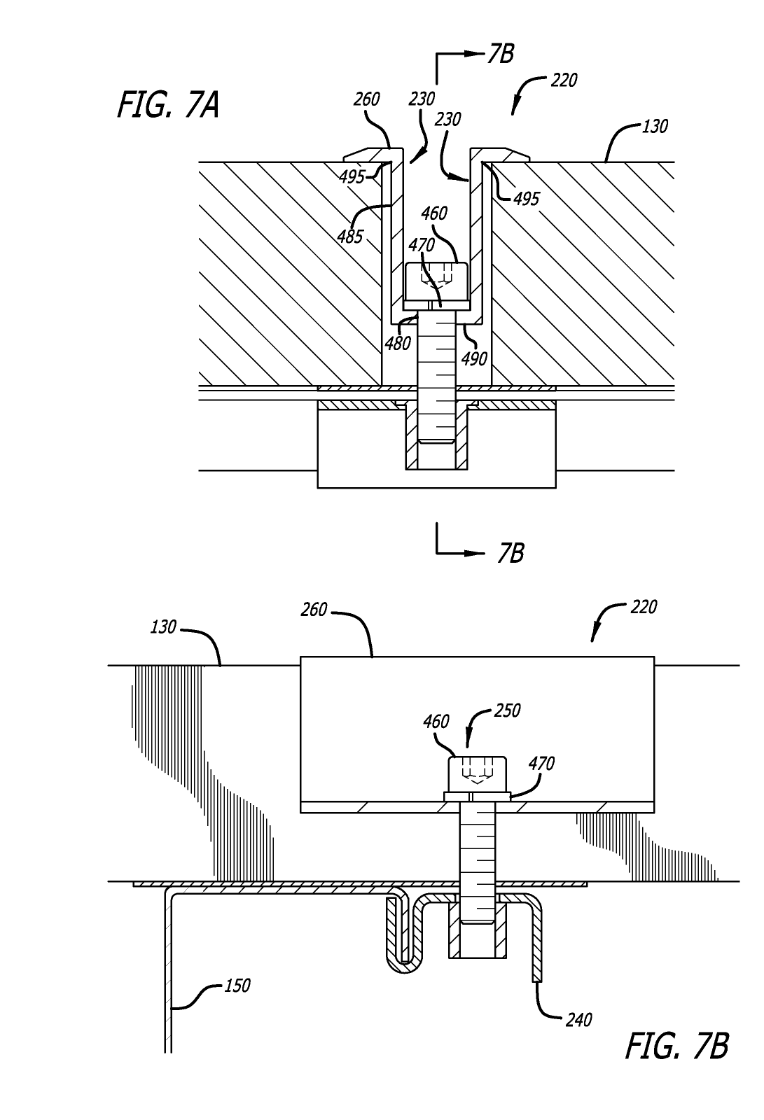

Hook portions 240 of pre-fabricated clamping assemblies 220 to be used for intermediate clamps 260 are positioned on the purlin 150 at a point where two photovoltaic modules 130 are to be placed next to each other on the fixed-axis mounting frame 120. As indicated in FIG. 6, which shows an isometric close-up view of a pre-fabricated clamping assembly 220 and an intermediate clamp 260, intermediate clamps 260 are then fastened to the hook portion 240 with screwing mechanism 250. As shown in FIG. 7, each intermediate clamp 260 includes at least one hole 480 in a base portion 490 thereof. Screwing mechanism 250 includes a screw 460, such as a M8 Allen screw, and a grover 470, such as for example a split ring locking washer, to secure the screw which, when applied to the hook portion 240 and the hole 480 in the base portion 490 of the intermediate clamp 260, causes force to be applied to the purlin 150 by the hook portion 240 as the screwing mechanism 250 is tightened. In this manner, the intermediate clamp 260 is secured to the fixed-axis mounting frame 120 without the need for extra fasteners to be applied directly to the purlin 150, making installation of photovoltaic modules 130 much easier and faster. A rubber material, such as for example pad made from ethylene propylene diene monomer (EPDM), may also be included in a clamping assembly 220 to protect against damage, such as scraping, wear-and-tear, and generating of unwanted electrical charge resulting from metal parts in contact with each other.

Intermediate clamps 260 are shaped in such a way that edges of different photovoltaic modules 130 can held securely in place, together, by the same intermediate clamp 260. As shown in FIG. 5, FIG. 6, and FIGS. 7A and 7B, intermediate clamps 260 have a base portion 490 formed as a “U” shape with two flared-out ends 495, to form an overall “omega” shape. Edges of photovoltaic modules 130 fit within the space created by the “omega” shape on the outside surface 485 of each intermediate clamp 260. In this manner, the thickness of a photovoltaic module 130 is not a primary consideration in installing modules 130 onto a fixed-axis mounting frame 120, since a flared-out portion 495 of each intermediate clamp 260 comes into contact with only one edge of each photovoltaic module 130.

Intermediate clamps 260 of pre-fabricated clamping assemblies 220 allow multiple photovoltaic modules 130 to be installed onto a fixed-axis mounting frame 120 of a photovoltaic mounting apparatus 100, and they can be installed in either a portrait or a landscape configuration. FIG. 5 shows photovoltaic modules 130 being loaded in a portrait configuration, as in a top-to-bottom or vertical manner, with intermediate clamps 260 being positioned so that the flared-out portions 495 of the “omega” shape are substantially perpendicular to a length of the purlin 150 to which the intermediate clamp 260 is applied. Regardless, it is to be understood that modifications or adjustments, as described herein, also permit a landscape installation of photovoltaic modules 130.

Intermediate clamps 260 and pre-fabricated clamping assemblies 220 also allow for single, double, or multi-portrait installation of photovoltaic modules 130. FIG. 5 indicates a double portrait installation in photovoltaic modules 130 are installed onto the fixed-axis mounting frame 120 from either top or the bottom. The installation is double due to two rows of photovoltaic modules 130 being installed in portrait fashion. It is to be understood that the purlins 150 of the fixed-axis mounting frame 120, and the pre-fabricated clamping assemblies 220, allow many different numbers of rows or columns of photovoltaic modules 130 to be installed, depending upon the use, customer or project requirements 390 and the environmental conditions or requirements 380.

As noted above, while FIG. 5 shows a top-to-bottom double portrait installation process, a landscape installation process is also possible by turning the orientation of the intermediate clamp 260 so that the flared-out portions 495 of the “omega” shape are substantially parallel with the purlin 150 to which the intermediate clamp 260 is applied. In this embodiment, the “omega” shape of the intermediate clamps 260 secure photovoltaic modules 130 together parallel to a length of each purlin 150 on a top and/or bottom of a photovoltaic module 130, as opposed to on the sides of photovoltaic modules 130 as shown in FIG. 5. The pre-fabricated nature of each clamping assembly 220 and lack of direct coupling to a purlin 150 allow intermediate clamps 260 to be turned to be either parallel or perpendicular to a length of a purlin 150, permitting either landscape or portrait installation. Likewise, end clamps 270, as discussed below, are configurable to secure photovoltaic modules 130 near an end of purlin 150 from the either side, or the top or bottom, as dictated by project, customer, or environmental needs.

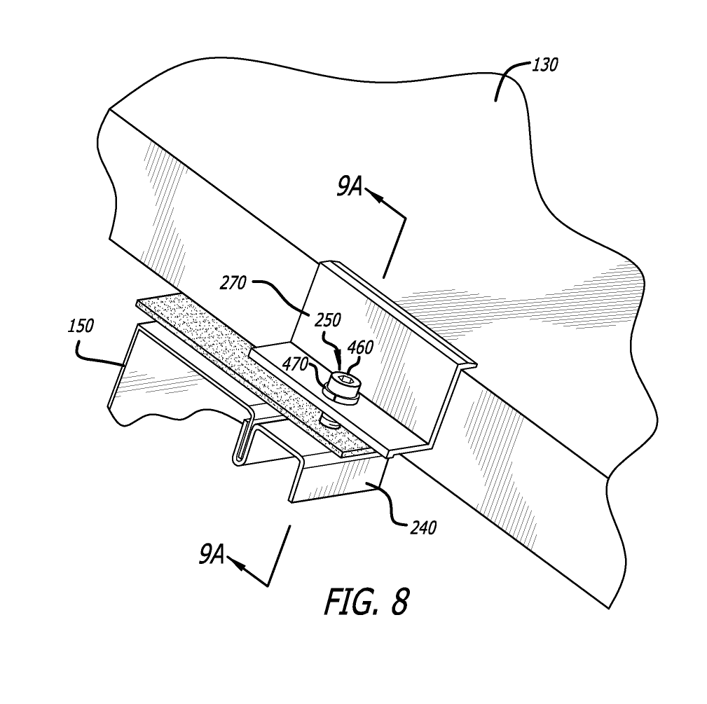

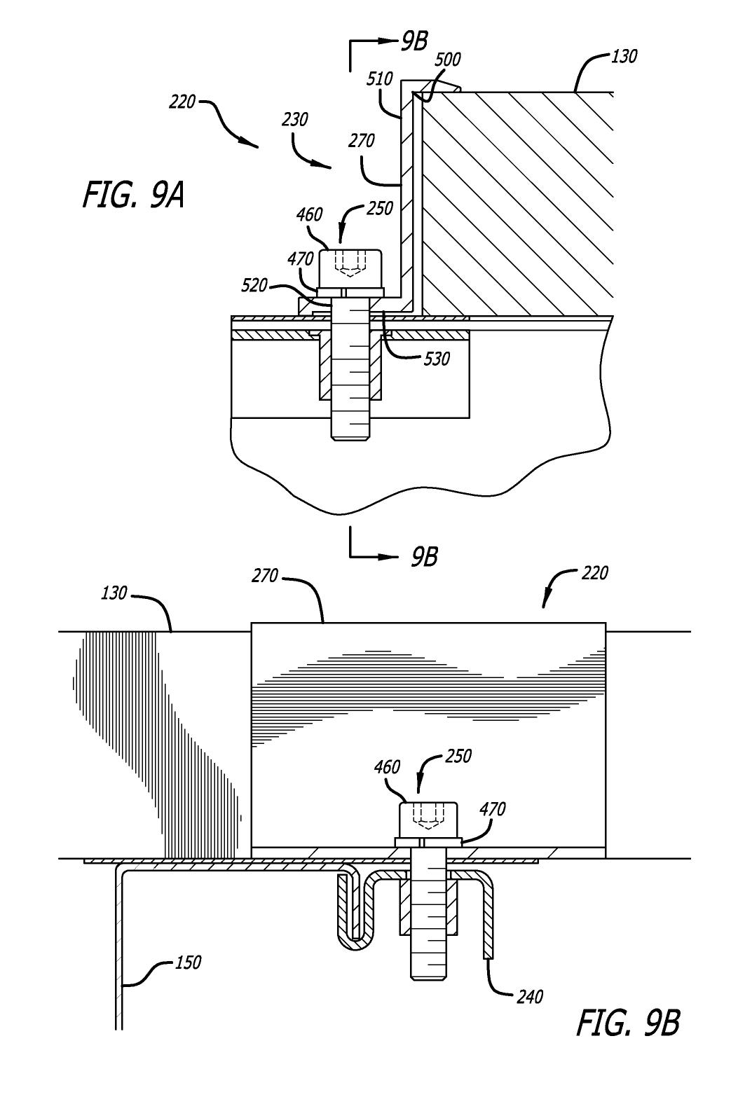

FIG. 8 is an isometric close-up view of a pre-fabricated clamping assembly 220 and an end clamp 270 securing a photovoltaic module 130 to a purlin 150 of a fixed-axis mounting frame 120. FIG. 9A and FIG. 9B are close-up side views of an end clamp 270. In both FIG. 8 and FIGS. 9A and 9B, end clamps 270 are formed as a “Z” shape with one flared-out end 500. Edges of photovoltaic modules 130 fit within the area created by the flared-out end 500 and the outside surface 510 of each end clamp 270, so that the thickness of a photovoltaic module 130 is not a primary consideration in installing modules 130 onto a fixed-axis mounting frame 120. Each end clamp 270 includes at least one hole 520 in a base portion 530 thereof.

Pre-fabricated clamping assemblies 220 with an end clamp 270 also include a screwing mechanism 250 includes a screw 460, such as for example a M8 Allen screw, and a grover 470, such as for example a split ring locking washer, to secure the screw. As with pre-fabricated clamping assemblies 220 having intermediate clamps 260, the screwing mechanism 250, when applied to the hook portion 240 and the hole 520 in the base portion 530 of the end clamp 270, causes force to be applied to the purlin 150 by the hook portion 240 as the screwing mechanism 250 is tightened. In this manner, the end clamp 270 is secured to the fixed-axis mounting frame 120 without the need for extra fasteners to be applied directly to the purlin 150, making installation of photovoltaic modules 130 much easier and faster. The screwing mechanism 250, and the force thereform that secures each end clamp 270 and hook portion 240 with a purlin 150 between them without any direct coupling to a purlin 150 permits the end clamp 270 to be aligned either parallel to or perpendicular to a length of a purlin 150. This allows photovoltaic modules 130 to be secured with the “Z”-shaped end clamp 270 on either side of the fixed-axis mounting frame 120 (and either side of a photovoltaic module 130) or on either the top or bottom of the fixed-axis mounting frame 120 (and either the top or bottom of a photovoltaic module 130). As with intermediate clamps, clamping assemblies 220 that include “Z” shaped clamps 270 may include a rubber material, such as for example an EPDM pad, to protect parts against possible damage.

End clamps 270 are also positionable at any point on a purlin 150. The “Z” shape of each clamp 270 allows an installation team to secure photovoltaic modules 130 in place on a fixed-axis mounting frame 120 at or near an end of a purlin 150, as well as at any point on a purlin 150 where another photovoltaic module 130 will not also be applied. Therefore, end clamps 270 may be used in conjunction with intermediate clamps 270 to secure multi-module photovoltaic module 130 configurations on a fixed-axis mounting frame 120, or with other end clamps 270 in either single or multi-module configurations. In different embodiments of the present invention, it is therefore a matter of designer, engineer, or installation team preference to determine whether end clamps 270 and intermediate clamps 260 may or need to be used together to secure photovoltaic modules 130.

It is to be understood, therefore, and as with pre-fabricated clamping assemblies 220 with intermediate clamps 260, end clamps 270 allow photovoltaic modules 130 to be installed in either a portrait or a landscape configuration.

Expansion of a photovoltaic mounting apparatus 100 according to the present invention is accomplished by introducing additional piles 110, transverse beams 140, and purlins 150, depending on the direction of expansion. When introducing additional purlins 150, the present invention contemplates at least two methods of securely adding additional components to ensure structural stability of the photovoltaic mounting apparatus 100. Purlins 150 may be added, in one embodiment, by coupling two purlins 150 together with a purlin connector 540 that fastens to outer surfaces 400 of both purlins 150. Apertures 550 near the ends 560 of the purlins 150 and in the purlin connectors 540 are used to fasten each purlin 150 to the purlin connector 540, as shown in FIG. 3. Purlin connectors 540 may include multiple apertures 570 to aid designers, engineers, and installers to account for variance in weather or other conditions that require slightly extra space between purlins 150. Regardless, purlin connectors 540 securely couple purlins 150 together, increasing the ability of designers, engineers, and installers to offer scalable, expandable photovoltaic mounting apparatuses 100, particularly where additional purlins 150 are needed and the design does not call for additional piles or transverse beams at the point where purlins 150 need to be connected.

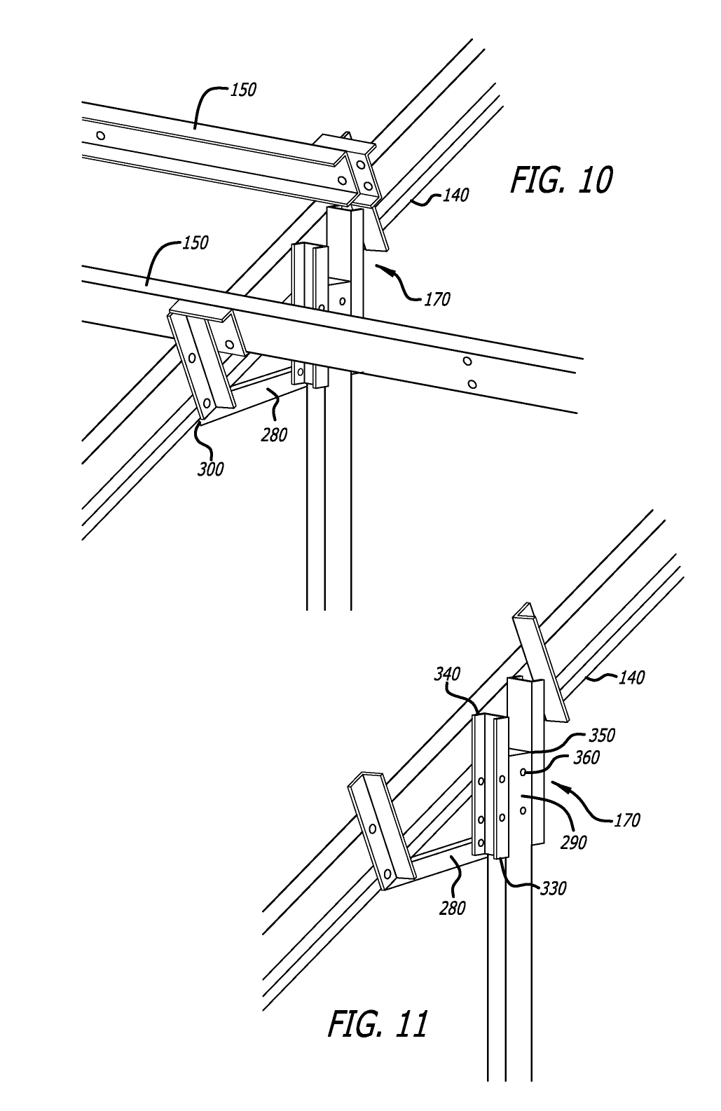

Purlins 150 may also be fastened together at the point where connective elements 160 couple a transverse beam 140 to a purlin 150. FIG. 10 shows an embodiment of a photovoltaic mounting apparatus 100 according to the present invention in which two purlins 150 are coupled together at the point where a transverse beam 140 is coupled to a purlin 150. In this embodiment, the connective elements 160 couple to an outer surface 400 of a purlin 150. Between the purlin 150 and the connective element 160 is the purlin connector 540, which as above includes multiple apertures 570 for fastening ends 560 of two purlins 150 together. Use of connective elements 160 in this manner substantially increases stability in the photovoltaic mounting apparatus 100.

In another embodiment of the present invention, connective elements 160 may themselves act as purlin connectors 540, so that an extra component is not needed, making it easier on the installation team to quickly install additional purlins 150. Connective elements 160 may therefore include a plurality of apertures 580 in multiple rows parallel with each other, so that one such row couples with an outer surface 400 of a purlin 150, but does not extend over an entire surface of the connective element 160. An additional row of apertures 580 is therefore free to couple to an outer surface 400 of another purlin 150, providing a connective element 160 that connects both purlins 150 to a transverse beam 140.

FIG. 11, which is a close-up view of an inclination assembly 170, also shows that additional apertures 590 in an inclination element 290 may be present to provide extra stability to the fixed-axis mounting frame 120 of the photovoltaic mounting apparatus 100. The additional apertures 590 allow an installer to fasten the inclination element 290 to the pile 110 in addition to the bracing element 280.

As noted herein, it is to be understood that the photovoltaic mounting apparatus 100 of the present invention is applicable to many other types of photovoltaic installations in open-area mounting situations that require different or specialized types of photovoltaic modules 130 and/or different or challenging terrain 210. For example, in addition to mono-crystalline and poly-crystalline applications, photovoltaic apparatuses 100 are also compatible for installation of frameless thin-film photovoltaic modules 130 such as for example FirstSolar® thin-film photovoltaic modules. Regardless of the type of photovoltaic modules 130 installed, open-area fixed-axis mounting frames 120 typically position photovoltaic modules between 500 mm and 1000 mm off of the ground. This is commonly done, for example, to ensure proper cooling of photovoltaic modules 130 to maintain operating efficiency; however, it is to be understood that installation can be customized to adjust the height relative to the ground to accommodate different installation parameters.

Other types of fixed-axis, open area photovoltaic mounting apparatuses 100 contemplated by the present invention include those for low-profile environments in which photovoltaic modules 130 do not need to positioned at a high distance from terrain (as in, for example, flat roofing situations as discussed herein) and for steep slope situations. Where photovoltaic mounting apparatuses 100 are to be installed in challenging terrain 210 conditions such as terrain 210 having a very steep slope, methods of installation include analyzing terrain slope as part of the study of land topography and other geotechnical considerations. In each specific case, materials selection is considered to arrive at an optimized parts and materials determination to ensure a quick and easy installation in all mounting situations and for all customer requirements with a minimum number of installation team members.

Installation of a photovoltaic mounting apparatus 100 of the present invention in steep-slope terrain 210 allows the fixed-axis mounting frame 120 to follow the slope of the terrain 210. This allows photovoltaic projects to be installed with a reduced environmental impact by eliminating the need the substantial earthworks at the installation site.

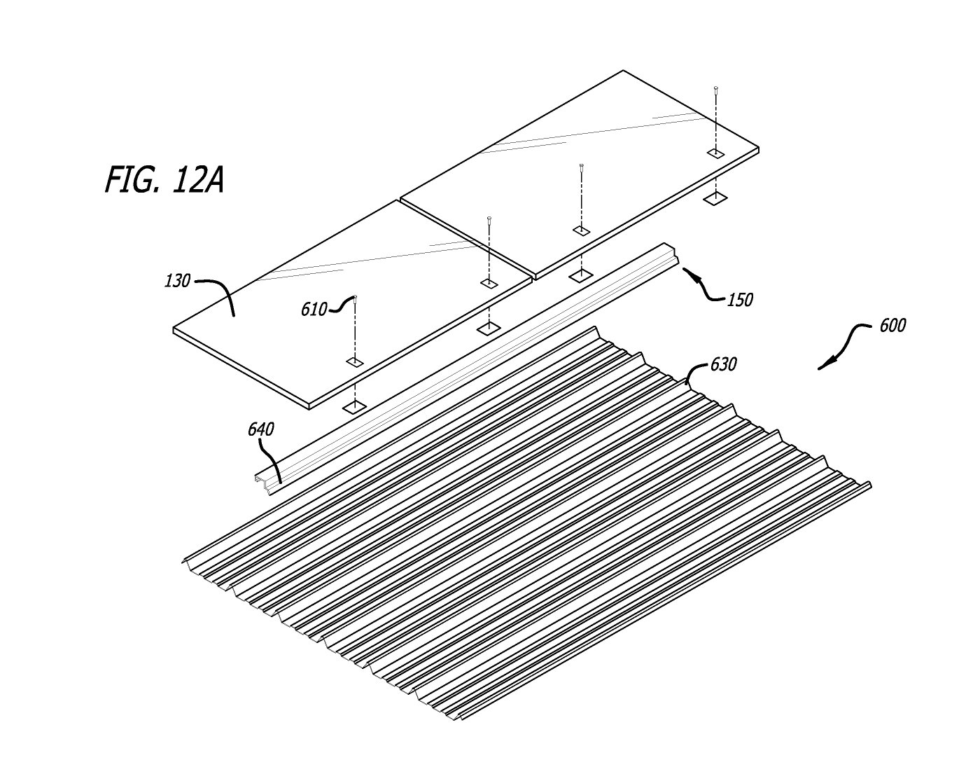

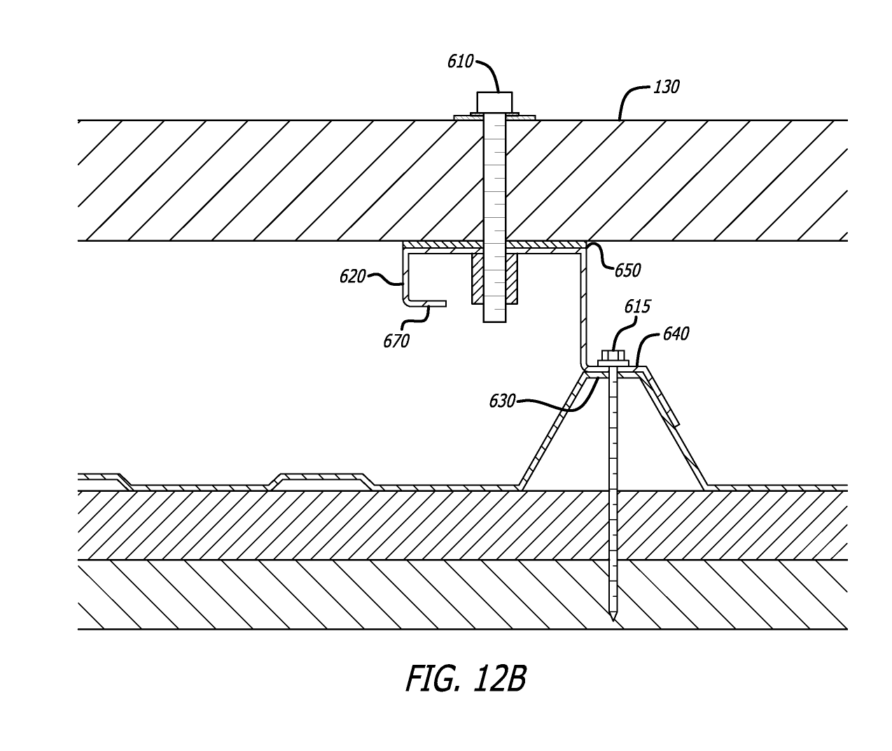

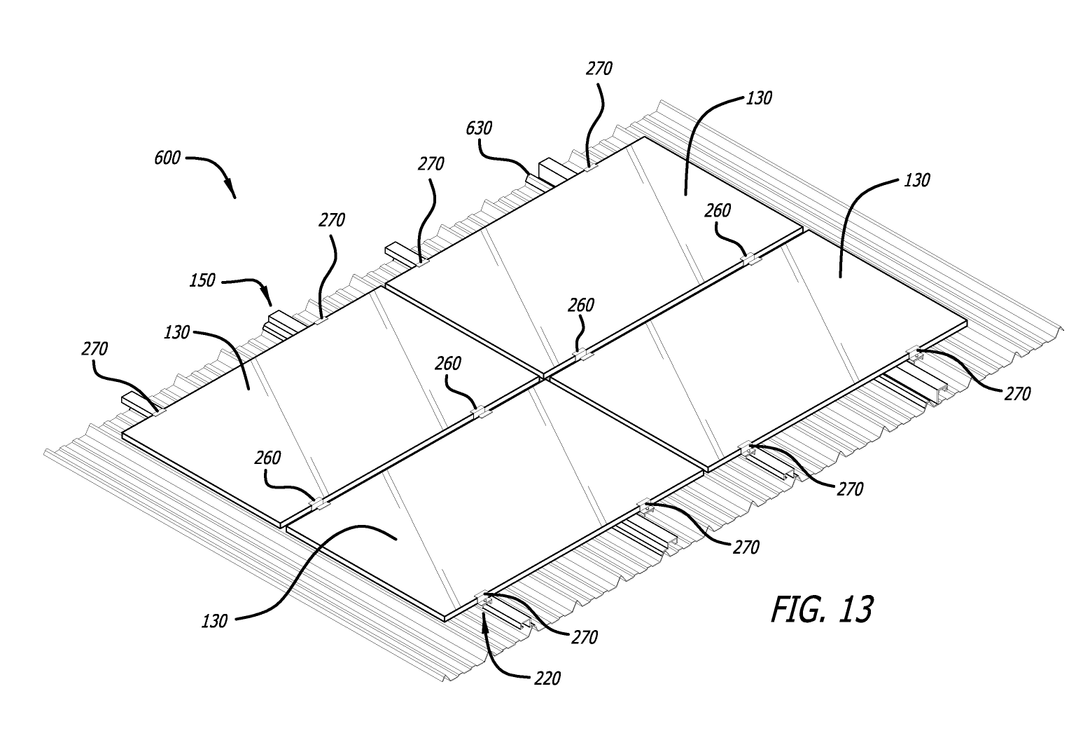

FIG. 12A is an exploded view of a photovoltaic mounting apparatus 100 for installation on industrial roofing according to one embodiment of the present invention, and FIG. 12B is a close-up sectional view of a photovoltaic mounting apparatus 100 according to this embodiment. FIG. 13 is another multi-dimensional view of a photovoltaic mounting apparatus 100 for industrial roofing according to this embodiment, in which photovoltaic modules 130 are installed in “landscape” format using hook portions 240. In this embodiment, the photovoltaic mounting apparatus 100 includes a purlin 150 which does not need to be adapted to have the same profile as an industrial roof section 600. The purlin 150 is first installed onto the industrial roof section 600 using screws 615, thereby securing the purlin 150 to the industrial roof section 600. Where needed, pre-fabricated clamping assemblies 220 are then applied to the purlin 150 by slidably positioning a hook portion 240 to the desired place on the purlin 150 on a mounting portion 620 of the purlin 150, and secured thereto in the same manner as above with no directly coupling to the purlin 150-instead, forces between a hook portion 240 and a clamp portion 230 when a screwing mechanism 250 is applied secure the pre-fabricated clamping assembly 220 to the purlin 150. Photovoltaic modules 130 are then installed onto the purlin 150 and secured thereto using screws 610.

Purlins 150 according to this embodiment of the present invention may be thought of as following a profile independent of the industrial roof section 600 onto which they are to be fastened. The present invention is therefore applicable to all types of industrial roofing panels and sheets, whether trapezoidal in shape or otherwise. Typical industrial roofing is comprised of sheets with a corrugated-type pattern with multiple trapezoidal sections 630. Purlins 150 according to this embodiment are designed to have a portion 640 which is adapted to affix to the profile of a trapezoidal section 630 of the industrial roof section 600. The portion 640 of the purlin 150 is fastened to this trapezoidal section 630 of the industrial roof section 600 using screws 615. The mounting portion 620 of each purlin 150 has a raised profile, and in the embodiment shown in FIG. 13, the hook portions 240 of the pre-fabricated clamping assemblies 220 are slidably positionable along the mounting portion 620 of the purlin 150. Regardless, the raised profile of the mounting portion 240 allows for a distance between the photovoltaic module 130 and the industrial roof section 600, which is particularly useful for cooling in hot climates. Cooling allows for the photovoltaic modules 130 to operate more efficiently in such conditions, since they typically experience drops in efficiency when the ambient temperature, and correspondingly their operating temperature, rises.

The mounting portion 620 of each purlin 150 therefore raises photovoltaic modules 130 slightly off of the surface of the industrial roof section 600 to allow for sufficient cooling of the photovoltaic modules 100. Purlins 150 can be machined to raise photovoltaic modules 130 higher or lower, but mounting portions 620 of standard purlins 150 raise photovoltaic modules 130 around 100 mm off of the surface of the industrial roof section 600. Mounting portions 620 includes a cornered end 650 with an outer surface 660, onto which photovoltaic modules 130 are mounted, a ridged portion 670, and an inner surface 680. The ridged portion 670 allows electrical cables 690 to be positioned underneath the mounting portion 620 along the inner surface 680 of a purlin 150 free of obstruction from other components and protected from weather conditions for providing electrical connections to components of the photovoltaic mounting apparatus 100. These electrical connections, as above, provide power to the photovoltaic modules 130 and photovoltaic mounting apparatus 100, and provide connectivity between photovoltaic modules 130 and inverters to harvest electricity and/or solar energy generated therefrom.

In a photovoltaic mounting apparatus 100 of the present invention, the design of the purlins 150 for installation on industrial roofing permits the installation team to improve the statical strength of the industrial roof section 600 with relation to the photovoltaic modules 130. Purlins 150 of this embodiment allow the load imposed by the weight of the photovoltaic modules 130 to be evenly distributed, and the installation team may then consider the appropriate number of purlins 150 to be selected for installation from one side to the other side of the structure onto which the photovoltaic mounting apparatus 100 is to be installed.

Pre-fabricated clamping assemblies 220 in this embodiment may be either intermediate clamps 260 or end clamps 270, and operate in the same manner as described above to permit installation of different numbers, sizes, and configurations of photovoltaic modules 130. It is possible, however, for photovoltaic modules 130 in industrial roofing situations to be installed in a portrait configuration without the need for hook portions 240 of the pre-fabricated clamping assemblies 220. This allows for an even easier installation process when a portrait configuration is selected, as the pre-fabricated clamping assemblies 220 are coupleable directly to a purlin 150 using just the screwing mechanism 250. Regardless, photovoltaic modules 130 may be installed in either in portrait or landscape configuration, and multiple rows or columns of photovoltaic modules 130 may be installed as desired. It follows that pre-fabricated clamping assemblies 220 in this embodiment of the present invention are also positionable either parallel to or perpendicular to purlins 150, allowing easy customization of the installation of photovoltaic modules 130.

In one aspect of the present invention in conjunction with industrial roofing applications, the photovoltaic mounting apparatus 100 is fastened to beams that support trapezoidal sections 630 of the industrial roof section 600, and not only to the metal sheet cladding forming the industrial roof section 600, using screws 615. In this aspect of the present invention, the metal sheet cladding is penetrated at pre-defined points, and rubber flanges are used to ensure waterproofing of the building were the metal sheet cladding is penetrated.

In yet another embodiment involving industrial roofing applications, the present invention may be provided to customers as a complete installation package that includes the roof section 600, the photovoltaic mounting apparatus 100, one or more photovoltaic modules 130, and all other required components. An industrial roofing installation according to this embodiment of the present invention may therefore be simplified for installation purposes to include a pre-fabricated industrial roofing onto which the photovoltaic mounting apparatus 100 will be screwed, to be installed for different flat roofing customers without need to consider existing industrial roofing components already in place. The installation team is therefore much more free to install photovoltaic modules 130 to maximize customer requirements. Accordingly, a photovoltaic mounting apparatus 100 according to this embodiment may include one or more portions of an industrial roof section 600, together with purlins 150, pre-fabricated clamping assemblies 220 and hook portions 240 (where needed) as well as photovoltaic modules 130.

The photovoltaic mounting apparatus 100 of the present invention is applicable in many other roof mounting situations. For example, in addition to industrial roofing applications, photovoltaic apparatuses 100 are capable of installation in other roofing applications, such as with flat roofing and with tile roofing.

In flat roofing installations, photovoltaic mounting apparatuses 100 are secured with either chemical anchoring or with a concrete ballast foundation system. In chemical anchoring, the photovoltaic mounting apparatus 100 is secured to the roof surface with either chemical or mechanical anchors. In concrete anchoring, the photovoltaic mounting apparatus 100 is installed with weighted ballast, such as flagstones or other available materials, including concrete blocks and gravel. In either situation, the photovoltaic mounting apparatus 100 is weighted down and does not require penetration of the roof for fastening, allowing for easy and quick installation with a minimum number of installation team members.

Photovoltaic modules 130 installed onto fixed-axis mounting frames 120 in flat roofing situations may be installed in single, double, or multi-panel arrangements in either portrait or landscape configurations. Angles of inclination of the fixed-axis mounting frame 120 relative to the roof surface may vary, usually in a range of between 10° and 40°, and all commercial types of photovoltaic modules 130 are capable of being positioned thereon. The photovoltaic modules 130 are raised a distance of around 100 mm, although it is to be understood that any distance that allows for sufficient cooling, depending on the type and configuration of photovoltaic modules 130, is acceptable. In one embodiment of a flat roofing-type mounting system, piles 110 may be anchored to foundation beams, which are themselves anchored to the roof surface, to provide support for multiple fixed-axis mounting frames 120.

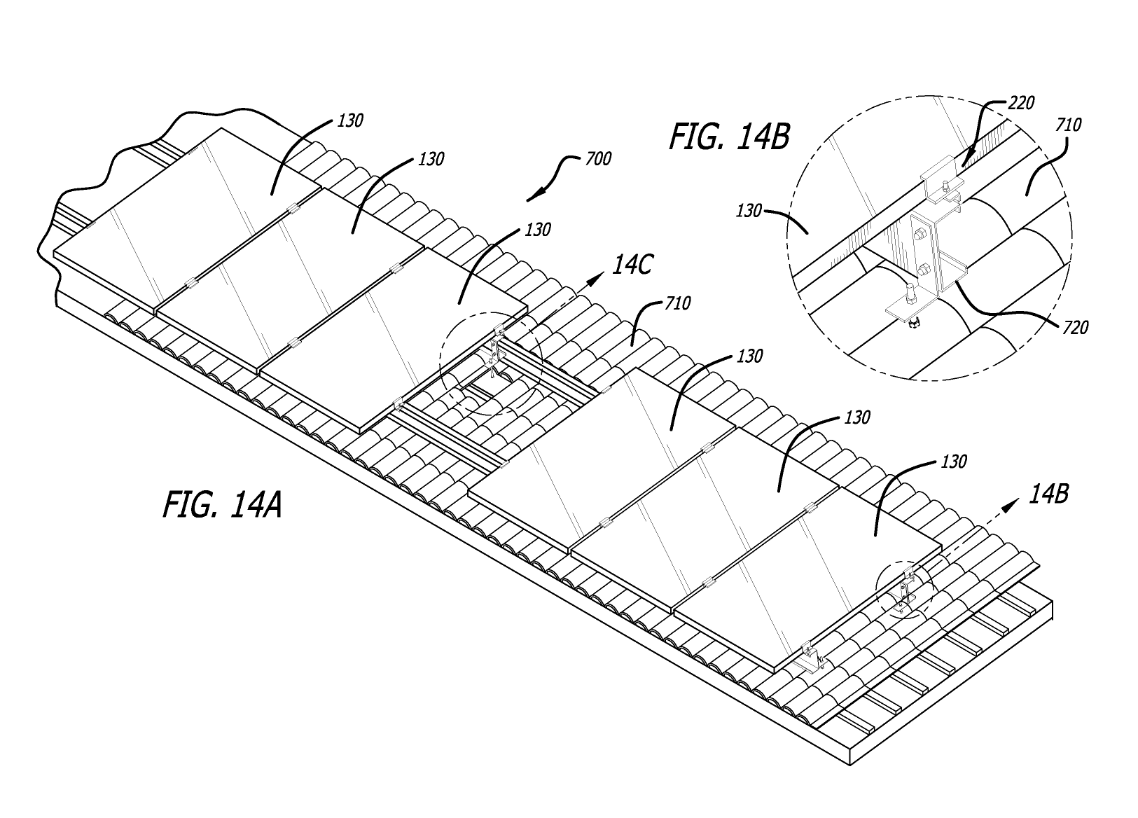

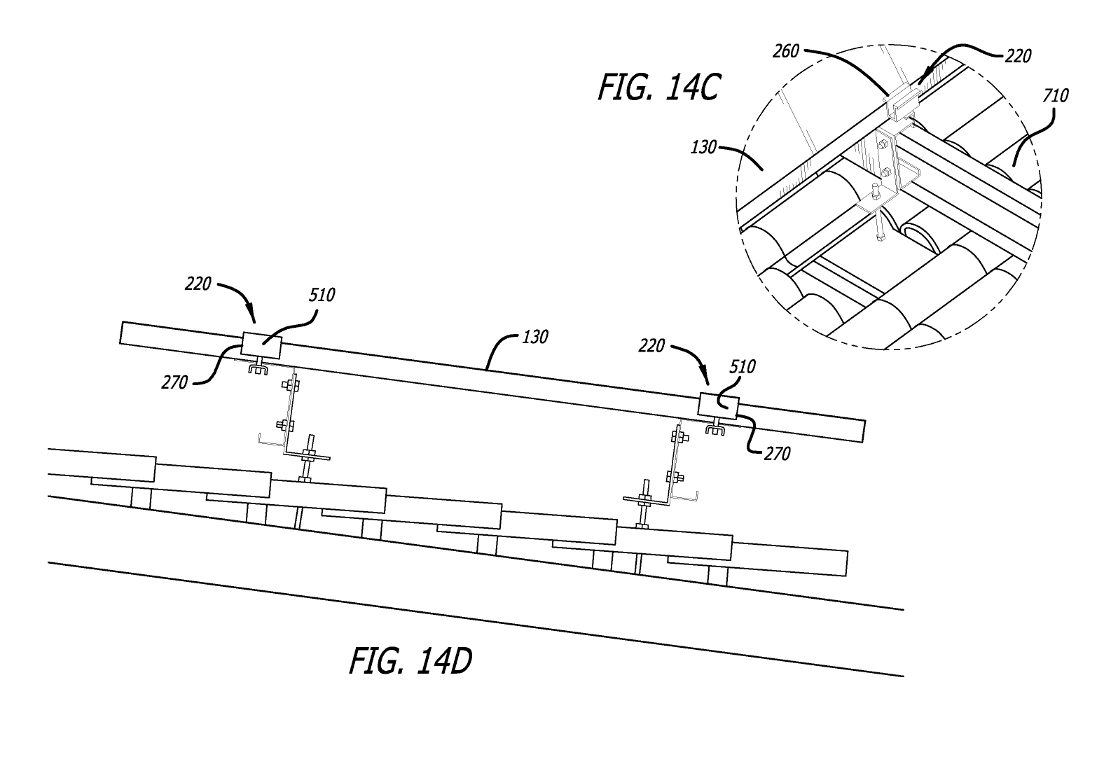

FIGS. 14A-14D are various views of a photovoltaic mounting apparatus 100 in a tile roof installation according to another embodiment of the present invention. In tile roofing installations, photovoltaic mounting apparatuses 100 are secured by anchoring a support structure to the roof surface and below the tiling with either chemical or mechanical anchors. Photovoltaic modules 130 may be installed in multi-panel arrangements in either portrait or landscape configurations. Angles of inclination of the fixe-axis mounting frame 120 relative to the roof surface may vary, usually in a range of between 10° and 40°, and all commercial types of photovoltaic modules 130 are capable of being positioned thereon. The photovoltaic modules 130 are raised a distance of around 100 mm, although it is to be understood that any distance that allows for sufficient cooling, depending on the type and configuration of photovoltaic modules 130, is acceptable.

FIG. 14A shows a partially exploded view of a photovoltaic mounting apparatus 100. In this embodiment, purlins 140 installed onto a tile roof section 700 and anchored below tiles 710 thereon. Clamping assemblies 220 secure photovoltaic modules 130 to the purlins 140. Purlin-tile connectors 720 couple purlins 140 to the tiles 710 and anchor to the tile roof section 700. FIG. 14B shows a close-up view of a purlin 140, clamping assembly 220, and purlin-tile connector 720, with the photovoltaic mounting apparatus 100 anchored to a tile roof section 700. The clamping assembly 220 in FIG. 14B includes a clamp portion 230 in a “Z” configuration. FIG. 14C shows a close-up view of a purlin 140, a clamping assembly 220 with a clamp portion 230 in an “omega” configuration, and a purlin-tile connector 720. In FIG. 14C, the photovoltaic mounting apparatus 100 is shown anchored below a tile 710 to the tile roof section 700. FIG. 14D shows a side view of an end of a photovoltaic mounting apparatus 100 anchored to the tile roof section 700, with photovoltaic modules 130 mounted thereon using clamping assemblies 220.

A pile 110 according to the present invention provides a foundation for the photovoltaic mounting apparatus 100 as described above, in either a single-pile arrangement involving the use of one pile 110 or a multi-pile arrangement such as a double pile 110. Regardless, in one aspect of the present invention, installation of a photovoltaic mounting system 110 requires an assessment of the terrain 210, use, customer or project requirements 390, and environmental conditions or requirements 380 within which the photovoltaic mounting apparatus 100 will be required to perform. Such an assessment is used to determine a type of foundation to be applied to the photovoltaic mounting apparatus 100.

Installation of any ground-mounted photovoltaic mounting apparatus 100 according to the present invention therefore requires a number of different considerations to determine the most appropriate type of foundation to be applied. Environmental conditions or requirements 380 may be important factors, and often include an assessment of weather conditions and patterns, a slope of terrain, and geotechnical characteristics of the soil.

Geotechnical characteristics are determined by one or more tests, such as a ramming test to determine ground suitability for anchoring a photovoltaic mounting apparatus 100. A geotechnical analysis is another test that may be performed to determine structural strength at different layers of the soil. Other tests performed include a land topography study, determining soil pH, and examining the type of soil before a decision as to the most appropriate foundation is finalized.

Other tests that may be conducted to determine an optimum mounting installation and apparatus include analyzing customer and use requirements, such as making a determination of customer photovoltaic module specifications. Considerations that may be taken into account include the suggested size of the installation in terms of much power is to be generated, whether the installation is to be on-grid or off-grid, downstream purchasers of power generated, commodity market prices for power generated, and budgetary issues. Geological studies of the proposed installation site may also be performed, as well as a site testing schedule, prior to installation of the photovoltaic mounting apparatus 100.

One embodiment of a method of installation of a photovoltaic mounting apparatus 100 of the present invention involves ramming a steel beam 180 of the pile 110 in the ground. In this embodiment, where a rammed, or pile-driven, foundation is determined to be most appropriate, the installation team rams the pile 110 into the ground, typically to depths of up to 2 meters. The specific depth is determined based on one or more of the terrain 210 and soil conditions described above. The foundation end 200 of the pile 110 anchors the pile 110 firmly into the ground by flaring out, or expanding laterally, upon the reaction of soil forces at the chosen depth. The soil forces alter the shape of the foundation end 200 and expanding the surface area of the foundation end 200 which anchors to the soil.

Another embodiment of the method of installation of a photovoltaic mounting apparatus 100 of the present invention involves drilling a hole into the terrain 210 and inserting the foundation end 200 of the steel beam 180 of the pile 110 into the hole. This embodiment, performed where soil characteristics such as its chemical composition indicate that ramming is not suitable and requires more strength in a foundation of the photovoltaic mounting apparatus 100, further requires filling the hole with concrete or another suitable material to surround, stabilize, and firmly support the pile 110. Other suitable materials may include the material that was itself extracted from the hole, if it exhibits suitably strong characteristics, and others such as gravel or a different type of soil. Alternatively, the hole may first be filled with such materials (concrete, gravel, a different type of soil), followed by the pile 110 being rammed into the hole.

Yet another embodiment of the method of installation of a photovoltaic mounting apparatus 100 of the present invention involves constructing a concrete foundation. In this embodiment, no ramming or drilling is performed; instead, concrete counterweights are positioned on the ground, and the foundation of the mounting system is achieved using chemical anchors on the counterweights.

Regardless of the type of foundation, design and installation of each photovoltaic mounting apparatus 100 of the present invention is performed in accordance with applicable structural codes, such as the Eurocode Actions on Structures, Design of Steel Structures, and Design of Structures for Earthquake Resistance. National and local codes are also fully implemented into the design and installation process.

It is to be understood that other embodiments will be utilized and structural and functional changes will be made without departing from the scope of the present invention. The foregoing descriptions of embodiments of the present invention have been presented for the purposes of illustration and description. It is not intended to be exhaustive or to limit the invention to the precise forms disclosed. For example, the present invention contemplates that end and intermediate clamps, and by extension clamping assemblies, may be modified to accommodate photovoltaic modules of any size, shape, or configuration, including photovoltaic panels that are parabolic in shape. Further, the clamping assemblies may be motorized so that they may be remotely controllable to change axis, or position, as in a tracking mounting system. In another example, the inclination assembly of the present invention may also be configured to move between a fixed, single axis and a single or double tracking mounting system, so that the angle of inclination can be changed as needed during the course of use of the photovoltaic mounting apparatus 100. Accordingly, many modifications and variations are possible in light of the above teachings. It is therefore intended that the scope of the invention be limited not by this detailed description.

1. A photovoltaic mounting apparatus, comprising:
a plurality of purlins, each purlin coupled to a plurality of transverse beams with one or more connective elements to form a fixed-axis mounting frame, and at least one inclination assembly connecting each transverse beam in the plurality of transverse beams of the fixed-axis mounting frame to a pile, each at least one inclination assembly including a bracing element connecting the pile to each transverse beam at a first connection point on the transverse beam, and an inclination element connecting the bracing element to the transverse beam at a second point on the transverse beam, each inclination element having a plurality of apertures for connecting to the second connection point on the transverse beam to form an adjustable angle of inclination of the fixed-axis mounting frame relative to the pile, each pile configured to anchor the fixed-axis mounting frame to terrain as determined by one or more environmental conditions; and
a plurality of intermediate clamps each removably and adjustably disposed at any point along a purlin to secure photovoltaic modules together, and a plurality of end clamps each removably and adjustably disposed near ends of a purlin to secure a photovoltaic module in place on the fixed-axis mounting relative to an intermediate clamp, each of the intermediate clamps and each of the end clamps having an aperture through which a screwing mechanism firmly connects each clamp to a hook slidably disposable along an edge of a purlin with tension applied between the hook and the clamp, so that each hook, clamp, and screwing mechanism form a clamping assembly that is removably positionable at a desired point on a purlin and firmly couples to the purlin to allow photovoltaic modules to be slidably and securely mounted onto the fixed-axis mounting frame and to allow one or more electrical cables to be positioned along an inner surface of each purlin to be free of interference from weather elements.

2. The mounting apparatus of claim 1, wherein the one or more environmental conditions include weather conditions, a slope of terrain, and geotechnical characteristics of soil, the geotechnical characteristics of soil determined by a plurality of tests that include a ramming test, a geotechnical analysis, a soil pH test, and a study of land topography.

3. The mounting apparatus of claim 2, wherein the pile is a steel beam rammed into the terrain to a calculated depth, and one or more forces acting upon the pile at the calculated depth changes a shape of an end of the pile to firmly anchor the pile to the terrain.

4. The mounting apparatus of claim 2, wherein the pile is a hole drilled into the terrain with a steel beam inserted into the hole and an area between the steel beam and the hole filled with a material to firmly support the steel beam in the hole.

5. The mounting apparatus of claim 2, wherein the pile is a concrete foundation.

6. The mounting apparatus according to claim 1, further comprising a plurality of piles each having an inclination assembly coupling the pile to the fixed-axis mounting frame at the adjustable angle of inclination.

7. The mounting apparatus of claim 1, where each photovoltaic module is slidably mounted on the fixed-axis mounting frame in a portrait configuration.

8. The mounting apparatus of claim 1, wherein each clamping assembly is pre-fabricated to mount on any purlin of the fixed-axis mounting frame, and configured so that the screwing mechanism is maneuverable to turn each intermediate clamp to secure multiple photovoltaic modules mounted either in a portrait configuration or a landscape configuration, and to turn each end clamp to secure a photovoltaic modules either at a left or right side of the fixed-axis mounting frame or at a top or a bottom of the fixed-axis mounting frame.

9. A method of installing a photovoltaic mounting system, comprising:
anchoring a pile with an appropriate foundation optimally determined by analyzing environmental conditions and the geotechnical characteristics of soil determined by a plurality of tests that include a ramming test, a geotechnical analysis, a soil pH test, and a study of land topography, so that the appropriate foundation provides an optimum support for a fixed-axis mounting frame coupled to the pile;
fastening the fixed-axis mounting frame to each pile at a desired angle of inclination determined by at least one of customer requirements and environmental conditions, the angle of inclination arranged with an inclination assembly that couples transverse beams of the fixed-axis mounting frame to the pile, the inclination assembly including a bracing element coupling to a first connection point on each transverse beam and an inclination element coupling to a second connection point on each transverse beam, the inclination element having a plurality of apertures through which the inclination element is adjustably coupleable to each transverse beam to form the desired angle of inclination relative to the pile;
positioning a plurality of pre-fabricated clamping assemblies onto purlins coupled to the fixed-axis mounting frame and removably securing each pre-fabricated clamping assembly to the purlins with a screwing mechanism so that tension applied between a hook and a clamp of each pre-fabricated clamping assembly slidably positions each pre-fabricated clamping assembly at a desired point on a purlin and firmly couples to a purlin, leaving an inner surface of each purlin; and
mounting one or more photovoltaic modules onto the purlins by slidably positioning each photovoltaic module onto the fixed-axis mounting frame between at least two of the pre-fabricated clamping assemblies, the plurality of pre-fabricated clamping assemblies including intermediate clamps configured to secure two photovoltaic panels together and end clamps configured to position panels between an end clamp and an intermediate clamp and near an edge of a purlin.

10. The method of claim 9, further comprising determining a customer photovoltaic module specifications, conducting a geological study of the proposed installation site, preparing a site testing schedule, and conducting a ramming test and a drilling test.

11. The method of claim 9, wherein the anchoring at least one pile further comprises anchoring a plurality of piles with the appropriate foundation.

12. The method of claim 9, further comprising ramming a steel beam into the terrain to a calculated depth so that one or more forces acting upon the steel beam at the calculated depth changes a shape of an end of the steel beam to firmly anchor the pile to the terrain.

13. The method of claim 9, further comprising drilling a hole into the terrain, inserting a steel beam into the hole, and filling an area between the steel beam and the hole with a material to firmly support the steel beam in the hole.

14. The method of claim 9, wherein the appropriate foundation is a concrete foundation.

15. The method of claim 9, wherein the mounting one or more photovoltaic modules onto the purlins further comprises mounting one or more photovoltaic modules on the fixed-axis mounting frame in a portrait configuration.

16. A customizable photovoltaic mounting system, comprising:
an inclination assembly coupling a transverse beam of a fixed-axis mounting frame to a support end of a pile at an angle adjustable according to at least one of customer and environmental requirements; and
a plurality of pre-fabricated clamping assemblies each having a hook portion slidably disposable along a ridged portion of a purlin and a clamp portion secured to the hook portion with a screwing mechanism so that one or more photovoltaic modules are securely positionable in a plurality of configurations according to the at least one of customer and environmental requirements on the fixed-axis mounting frame by a force exerted on the purlin between the hook and the clamping portion that permits each pre-fabricated clamping assembly to be adjusted and positioned, and a number of the pre-fabricated clamping assemblies used to be determined, according to the at least one of customer and environmental requirements, the purlin having an inner surface capable of housing a cable providing electrical connectivity to the one or more photovoltaic modules in a position protecting the cable from interference.

17. The system of claim 16, further comprising a plurality of transverse beams each coupled to a plurality of purlins, at least one pile in a plurality of piles, and at least one inclination assembly in a plurality of inclination assemblies, each pile coupled to a transverse beam by an inclination assembly to form a scalable photovoltaic mounting system capable of a size to be determined by the at least one of customer and environmental requirements.

18. The system of claim 16, wherein the pile further comprises a foundation end configured to anchor to terrain and rammed into the terrain to a calculated depth where one or more forces acting upon the foundation at the calculated depth changes a shape of the foundation end to firmly anchor the pile to the terrain.

19. The system of claim 16, wherein the pile further comprises a foundation end configured to anchor to terrain in a hole drilled into the terrain, the foundation end being inserted into the hole and an area between the foundation end and the hole filled with concrete.

20. The system of claim 16, wherein the pile further comprises a foundation end configured to anchor to terrain in concrete.
